(19) United States
(12) Patent Application Publication
(10) Pub. No.: US 2016/0218665 A1
(43) Pub. Date: Jul. 28, 2016

(54) SPACE SOLAR CELL PANEL WITH BLOCKING DIODES

(71) Applicant: SolAero Technologies Corp., Albuquerque, NM (US)

(72) Inventor: Kevin Crist, Sandia Park, NM (US)

(21) Appl. No.: 14/602,892

(22) Filed: Jan. 22, 2015

(51) Int. Cl. H02S 40/34; H02S 40/36; H01L 31/05

(52) U.S. Cl. CPC H02S 40/34; H01L 31/0504; H02S 40/36

(57) ABSTRACT

A solar cell assembly or sub-array that comprises a string of series connected solar cells, one of the solar cells being a final solar cell of the string of solar cells. The final solar cell has at least one oblique cut corner. The solar cell assembly further comprises a contact member connected to the final solar cell through a blocking diode, positioned in correspondence with the space provided by the space provided by the oblique cut corner.

### REFERENCE TO RELATED APPLICATIONS

This application is related to co-pending U.S. patent application Ser. Nos. 29/476,181 and 29/476,182 filed Dec. 11, 2013, herein incorporated by reference.

### BACKGROUND OF THE DISCLOSURE

1. Field of the Disclosure

The disclosure relates to the field of photovoltaic power devices.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells due to the space that is left between adjacent solar cells due to their circular configuration.

However, solar cells are often produced from circular or substantially circular wafers. For example, solar cells for space applications are typically multi junction solar cells grown on substantially circular wafers. These circular wafers are sometimes 100 mm or 150 mm diameter wafers. However, as explained above, for assembly into a solar array (henceforth, also referred to as a solar cell panel), substantially circular solar cells, which can be produced from substantially circular wafers to minimize waste of wafer material and, therefore, minimize solar cell cost, are often not the best option, due to their low array fill factor, which increases the overall cost of the photovoltaic array or panel and implies an inefficient use of available space. Therefore the circular wafers are often divided into other form factors to make solar cells. The preferable form factor for a solar cell for space is a rectangle, such as a square, which allows for the area of a rectangular panel consisting of an array of solar cells to be filled 100% (henceforth, that situation is referred to as a “fill factor” of 100%), assuming that there is no space between the adjacent rectangular solar cells. However, when a single circular wafer is divided into a single rectangle, the wafer utilization is low. This results in waste.

Space applications frequently use high efficiency solar cells, including multijunction solar cells based on III/V compound semiconductors. High efficiency solar cell wafers are often costly to produce. Thus, the waste that has conventionally been accepted in the art as the price to pay for a high fill factor, that is, the waste that is the result of cutting the rectangular solar cell out of the substantially circular solar cell wafer, can imply a considerable cost.

Thus, there is a trade-off between maximum use of the original wafer material and the fill factor. It is known in the art to try to strike a balance between the high waste produced when cutting perfectly rectangular solar cells out of a substantially circular solar cell wafer, and the poor fill factor that is obtained when using substantially circular solar cells. This is achieved by using solar cells having oblique cut corners, also referred to as cropped corners. Solar cells with cropped corners can be obtained from a substantially circular solar cell wafer, as schematically illustrated in FIG. 1E. This allows a substantial part of the wafer to be used for the production of a substantially octagonal solar cell. As the four oblique sides at the corners are shorter than the other four sides, the general layout of the solar cell is substantially rectangular or square, and a high fill factor is obtained when the solar cells are placed in an array to provide a substantially rectangular solar cell array. Some space is wasted at the corners of the solar cells, as the space where the solar cells meet at the cropped corners thereof will not be used for the conversion of solar energy into electrical energy. However, this wasted space only amounts to a relatively small portion of the entire space occupied by the solar cell array. Also, this space can be used to house other components of the solar cell assembly, such as bypass diodes.

FIG. 1A schematically illustrates the electrical circuit diagram of a triple junction solar cell 100 having a multijunction stack 101 comprising subcells 102, 103 and 104. The solar cell 100 is provided with electrical terminals 106 and 107, including contact pads 105, for connection via external connectors 114 and 115 to terminals 112 and 113 of a discrete bypass diode 110, including a diode device 111. FIG. 1B schematically illustrates how such a solar cell 100 can be connected in series with another solar cell 200, which can be connected in series with further solar cells, using interconnects 120 and 220.

FIGS. 1C and 1D illustrate the upper and the lower side, respectively, of a solar cell 100. Grid lines 108 are present at the upper side to collect the generated current, and are connected to a bus bar 107 including contact pads 105 disposed on the top surface at an edge of the solar cell. The lower side shown in FIG. 1D is provided with a metal layer 106 covering the entire lower side of the solar cell. The top surface or contact 112 of the bypass diode 110 is connected to the bus bar 107 by a first connector 115, and the bottom surface or contact 113 of the bypass diode 110 is connected to the bottom metal layer 106 by a second connector 114. Due to its placement at a cropped corner and due to its connection to the solar cell 100 through two connectors 114 and 115, it has been found practical to use a bypass diode having a polygonal shape, such as the triangular shape of the bypass diode 110 of FIG. 1C. FIG. 1F illustrates the entire top surface of the solar cell, with four cropped corners and the bus bar 107 with contact pads 105 that can be used to interconnect the solar cell with other solar cells. FIG. 1G illustrates how the bypass diode 110 can be placed at one of the four corners.

Bypass diodes are frequently used for each solar cell in solar cell arrays comprising a plurality of series connected solar cells or groups of solar cells. One reason for this is that if one of the solar cells or groups of solar cells is shaded or damaged, current produced by other solar cells, such as by unshaded or undamaged solar cells or groups of solar cells, can flow through the by-pass diode and thus avoid the high resistance of the shaded or damaged solar cell or group of solar cells. Placing the by-pass diodes at the cropped corners of the solar cells can be an efficient solution as it makes use of a space that is not used for converting solar energy into electrical energy. As a solar cell array or solar panel often includes a large number of solar cells, and often a correspondingly large number of bypass diodes, the efficient use of the area at the cropped corners of individual solar cells adds up and can represent an important enhancement of the efficient use of space in the overall solar cell assembly.

In addition to the bypass diodes, a solar cell array or panel also incorporates a blocking diode that functions to prevent reverse currents during the time when the output voltage from a solar cell or a group of series connected solar cells is low, for example, in the absence of sun. Generally, only one blocking diode is provided for each set or string of series connected solar cells, and the blocking diode is connected in series with this string of solar cells. Often, since a panel includes a relatively large amount of solar cells that are connected in series, a relatively substantial blocking diode is required, in terms of size and electrical capacity. The blocking diode is generally connected to the string of solar cells at the end of the string. As the blocking diode is generally only present at the end of the string, not much attention has been paid to the way in which it is shaped and connected, as this has not been considered to be of major relevance for the over-all efficiency of the solar cell assembly. Standard diode components have been used.

FIG. 1H is a schematic circuit diagram of a solar cell 100 with bypass diode 110 as shown in FIG. 1A. A blocking diode 130 is connected in series with the solar cell 100 and, thus, in series with any further solar cells connected in series with solar cell 100. It can be considered that the blocking diode terminates a string of series connected solar cells. In FIG. 1H, the blocking diode 130 includes a terminal 136 that can be used to connect the blocking diode to a contact member at the end of the string of solar cells, and another terminal 135 connected to the metal layer 106 of the solar cell 100 by an interconnect 137.

### SUMMARY OF THE DISCLOSURE

A first aspect of the disclosure relates to a solar cell assembly comprising: a first string of series connected first solar cells, one of said first solar cells being a final first solar cell of the first string, said final first solar cell having at least one oblique cut corner; and at least one contact member connected to said final first solar cell through a first blocking diode. The first blocking diode is positioned in correspondence with said oblique cut corner. Thus, efficient use is made of the free space present between the contact member, such as a linear bus bar, and the solar cell, due to the cut off corner. In solar cell assemblies comprising solar cells, such as rectangular—often square—solar cells having oblique cut corners, there is often a space between adjacent solar cells and between solar cells and components such as linear bus bars or similar contact members, due to said oblique cut corners. By placing the first blocking diode in correspondence with an oblique cut corner, that is, in a space left free due to the cut-away corner portion, use is made of this space. Thereby, space utilization is enhanced.

In some embodiments of the disclosure, the first blocking diode has a substantially triangular shape adapted to fit into a space left free by said cut corner. That is, the first blocking diode can be fit into the space left free due to the absent corner, that is, the space that is formed between, for example, a linear contact member such as a linear bus bar, and the edge of the solar cell that is placed adjacent to the contact member.

In some embodiments of the disclosure, the contact member is a metal bus bar. This kind of metal bus bar is often linear and there is thus a space that remains free where the metal bus bar extends in correspondence with an oblique cut corner of a solar cell. Thus, by placing the blocking diode in said space, efficient use is made of said space.

In some embodiments of the disclosure, the solar cell assembly further comprises a second string of series connected second solar cells, one of said second solar cells being a final second solar cell of the second string, said final second solar cell being connected to a contact member through a second blocking diode, the final first solar cell and the final second solar cell being placed adjacent to each other, said first blocking diode being placed in correspondence with an oblique cut corner of said final first solar cell and said second blocking diode being placed in correspondence with an oblique cut corner of said final second solar cell, said first blocking diode and said second blocking diode being placed adjacent to each other. Thus, efficient use is made of the space left free by the cut corners where two solar cells at the end of respective strings of solar cells are placed adjacent to each other and adjacent to respective contact members. In some embodiments of the disclosure, the first blocking diode and the second blocking diode each have a substantially triangular shape. Thus, the space left free between two adjacent solar cells with oblique cut corners and, for example, one or two linear contact members such as linear bus bars, that is, a substantially triangular space, can be efficiently filled by two substantially triangular blocking diodes, for example, each having a size substantially corresponding to a cut corner of the respective solar cell.

In some embodiments of the disclosure, the final first solar cell is connected to the contact member through two blocking diodes, one of said two blocking diodes being placed in correspondence with a first oblique cut corner of the final first solar cell, and the other one of said two blocking diodes being placed in correspondence with a second oblique cut corner of the final first solar cell. Thus, the current produced by the entire string of series connected solar cells can be distributed between two blocking diodes, one placed in correspondence with one of the two cut corners and the other one being placed in correspondence with the other one of the two cut corners at the edge of the solar cell adjacent to the contact member. This enhances the efficient use of space between solar cells and between solar cells and contact members. In some embodiments of the disclosure, each of said two blocking diodes has a substantially triangular shape. This shape con enhance the efficient use of space, as it allows the blocking diodes to fit neatly into the space left free by the oblique cut corners.

In some embodiments of the disclosure, the contact member is a metal bus bar having a substantially rectangular shape. When this kind of substantially rectangular bus bar is placed adjacent to a solar cell having one or more cropped corners, that is, oblique cut corners, there will be an empty space between the edge of the solar cell and the metal bus bar in correspondence with the cut corners, and this space can be used to place a blocking diode.

Another aspect of the disclosure relates to a solar cell assembly comprising a plurality of solar cells arranged adjacent to each other in rows and columns forming an array, each solar cell having a substantially rectangular shape with four oblique cut corners, each of a plurality of the solar cells being connected to a bypass diode arranged in correspondence with an oblique cut corner of the respective solar cell and arranged in a space provided between adjacent solar cells at the oblique cut corners of the solar cells, the solar cell assembly further comprising at least one contact member arranged to collect current from a plurality of said solar cells arranged in series, at least one solar cell being connected to said contact member through at least one blocking diode, the at least one blocking diode being placed in a space provided between said at least one solar cell and the contact member, in correspondence with one of the oblique cut corners of said at least one solar cell. Thus, efficient use is made not only of the space between cropped corners of adjacent solar cells, but also of the space between the contact member and the edge of the solar cell in correspondence with one or two cropped corners of the solar cell that are placed facing the contact member. Thereby, the use of space is optimized also at the end of the string of series connected solar cells.

In some embodiments of the disclosure, the blocking diode has a substantially triangular shape. Blocking diodes having a substantially triangular shape allow for efficient use of the space between contact members and solar cells at the cropped corners of the solar cells, at the end of a string of interconnected solar cells.

In some embodiments of the disclosure, the blocking diode has a substantially square or rectangular shape.

In some embodiments of the disclosure, at least one solar cell is connected to the contact member through two blocking diodes, one of said blocking diodes being placed in a space provided between said at least one solar cell and the contact member in correspondence with one of the oblique cut corners of said at least one solar cell, and the other blocking diode being placed in a space provided between said at least one solar cell and the contact member in correspondence with another one of the oblique cut corners of said at least one solar cell. Thereby, the current produced by a string of solar cells can be distributed through two blocking diodes, said diodes making use of the space left between the cropped corners of the solar cell placed adjacent to the contact member, and the contact member.

In some embodiments of the disclosure, the contact member is a metal bus bar having a substantially rectangular shape. When this kind of substantially rectangular bus bar is placed adjacent to a solar cell having a cropped corner, that is, an oblique cut corner, there will be an empty space between the edge of the solar cell and the metal bus bar in correspondence with this cut corner, and this space can be efficiently used to place a blocking diode.

In some embodiments of the disclosure, two blocking diodes are placed in a space between two adjacent solar cells belonging to two strings of series connected solar cells, and two metallic contact members connected in series, a first one of said blocking diodes interconnecting a first one of said two adjacent solar cells and one of said two metallic contact members, and a second one of said blocking diodes interconnecting a second one of said two adjacent solar cells and another one of said two metallic contact members, the first blocking diode being placed in correspondence with an oblique cut corner of the first one of said two adjacent solar cells, and the second blocking diode being placed in correspondence with an oblique cut corner of the second one of said two adjacent solar cells. Thereby, efficient use is made of the space between the solar cells at the end of the strings of series connected solar cells, and the metallic contact members. In some embodiments of the disclosure, each of said two blocking diodes has a substantially triangular shape.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1A is a schematic circuit diagram of a solar cell, as known in the art.

FIG. 1 B is a schematic circuit diagram of two series connected solar cells, as known in the art.

FIGS. 1C and 1D schematically illustrate the upper side and the lower side, respectively, of a solar cell with a by-pass diode, as known in the art.

FIG. 1E schematically illustrates how a solar cell with cropped corners can be obtained from a circular wafer, as known in the art.

FIG. 1F schematically illustrates a solar cell with cropped corners and a busbar 107 for connection to other solar cells or components, as known in the art.

FIG. 1G schematically illustrates a bypass diode connected to the solar cell of FIG. 1F, as known in the art.

FIG. 1H is a schematic circuit diagram of a solar cell with bypass diode and blocking diode, as known in the art.

FIG. 2A schematically illustrates a solar cell with cropped corners;

FIG. 2B schematically illustrates how bypass and blocking diodes can be connected to the solar cell, at its cropped corners.

FIGS. 2C-2E are cross-sectional views of a solar cell at a corner featuring a blocking diode.

FIGS. 3A and 3B illustrate a metallic interconnection member used in correspondence with the blocking diode.

FIGS. 4A-4C are schematic top views of a solar cell assembly.

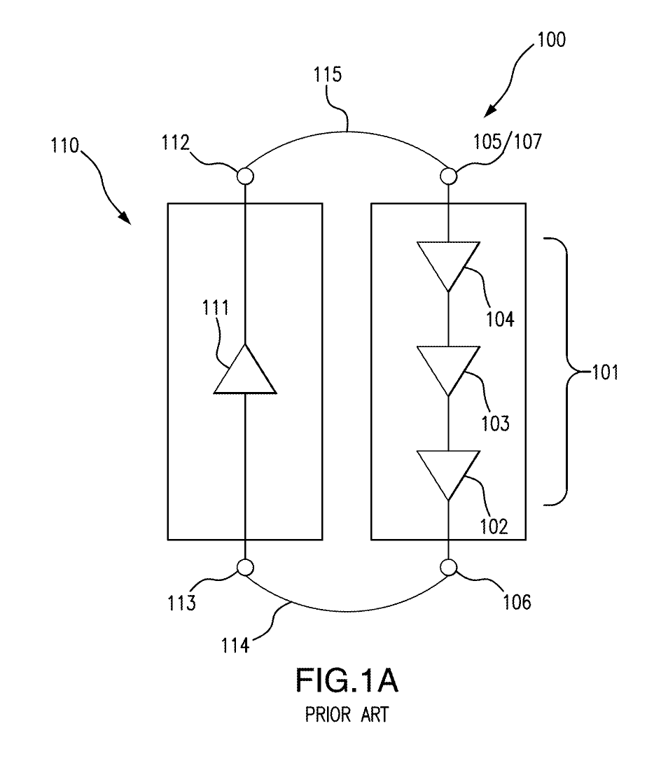

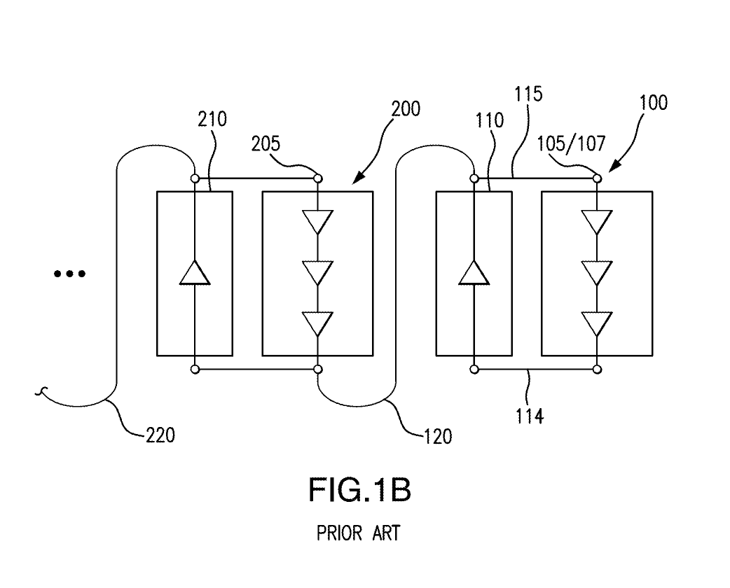

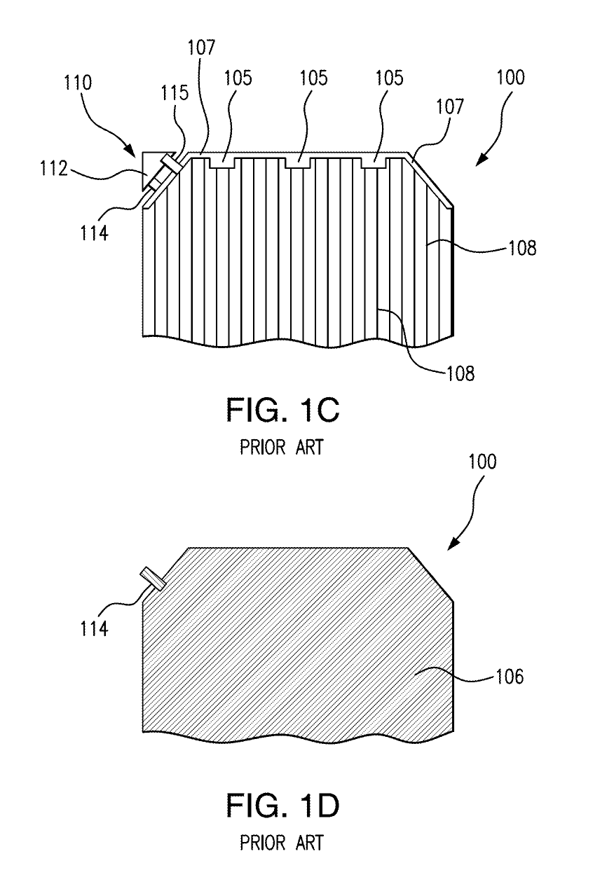

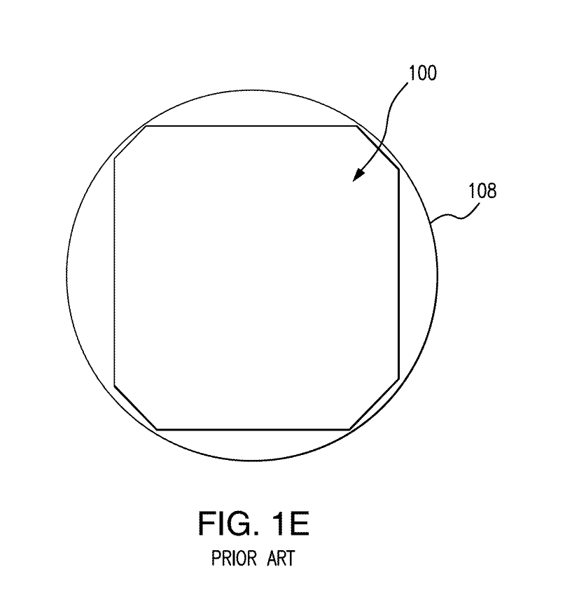

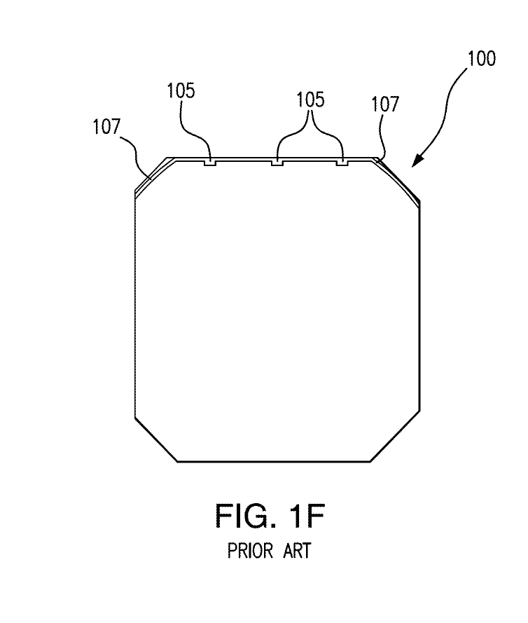

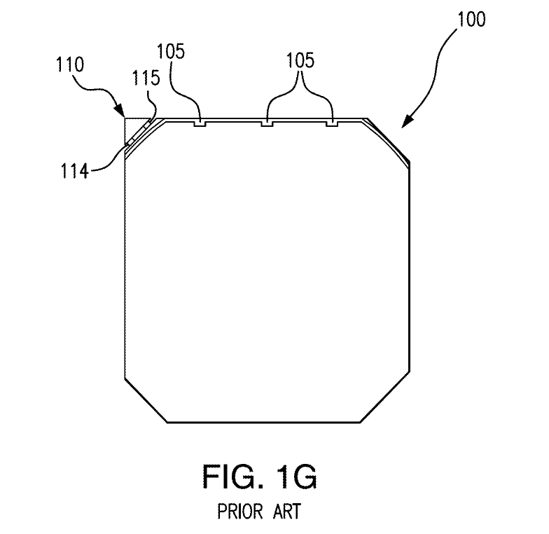

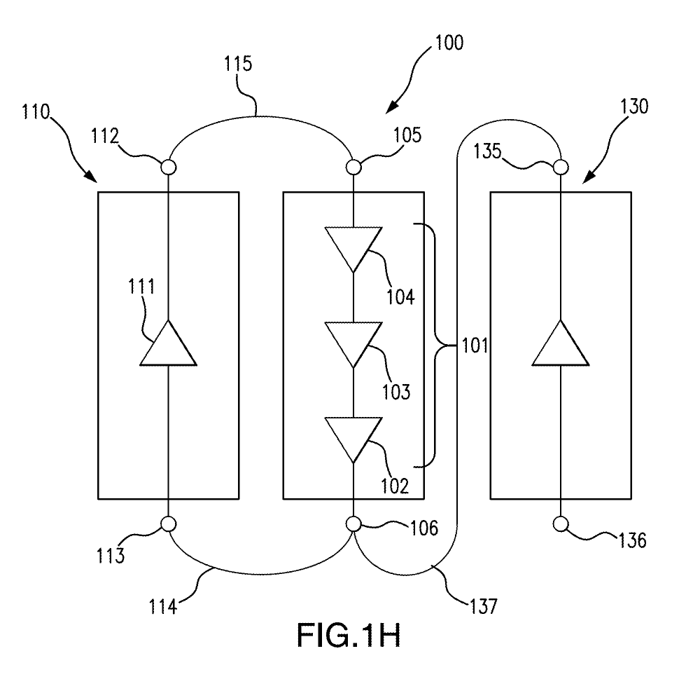

### DETAILED DESCRIPTION

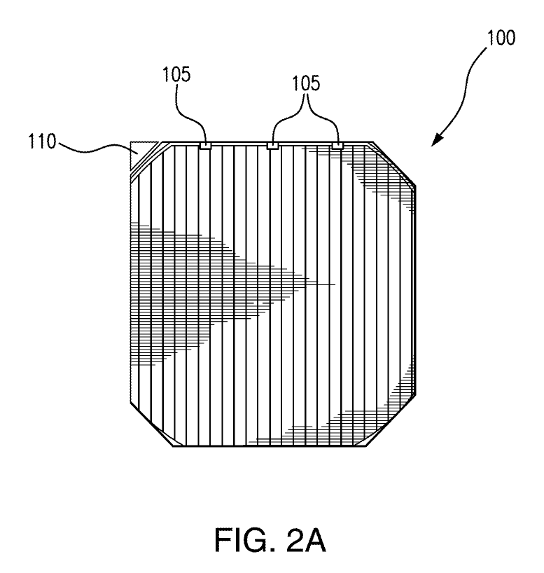

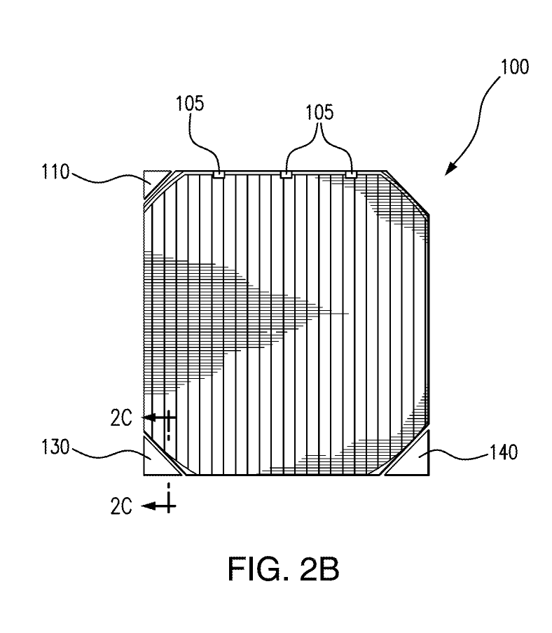

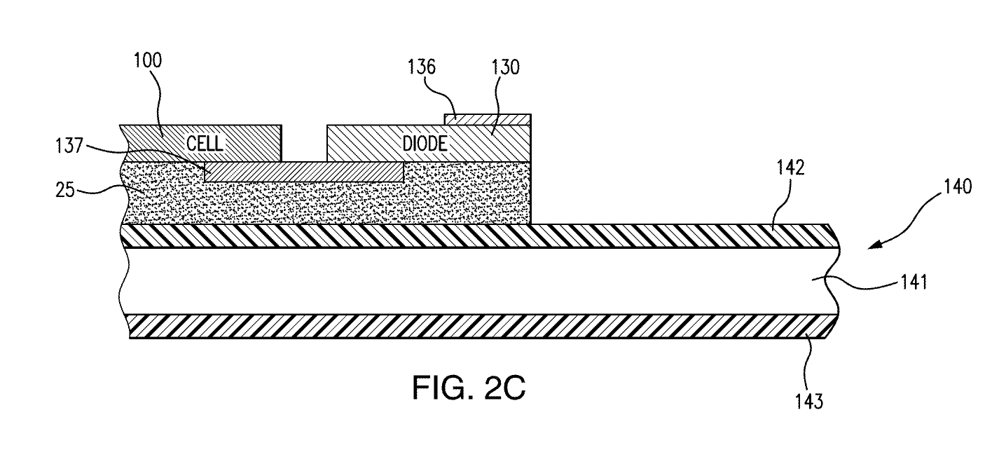

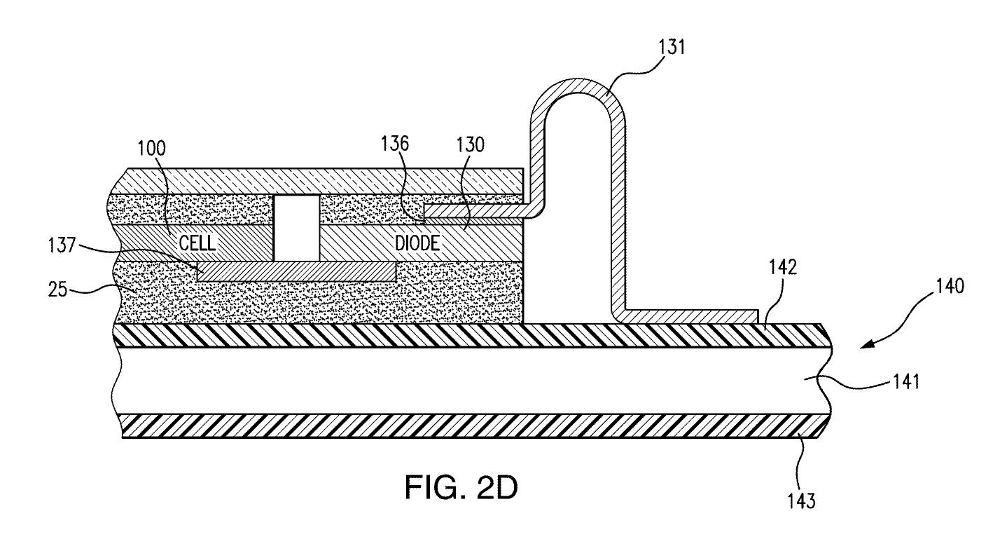

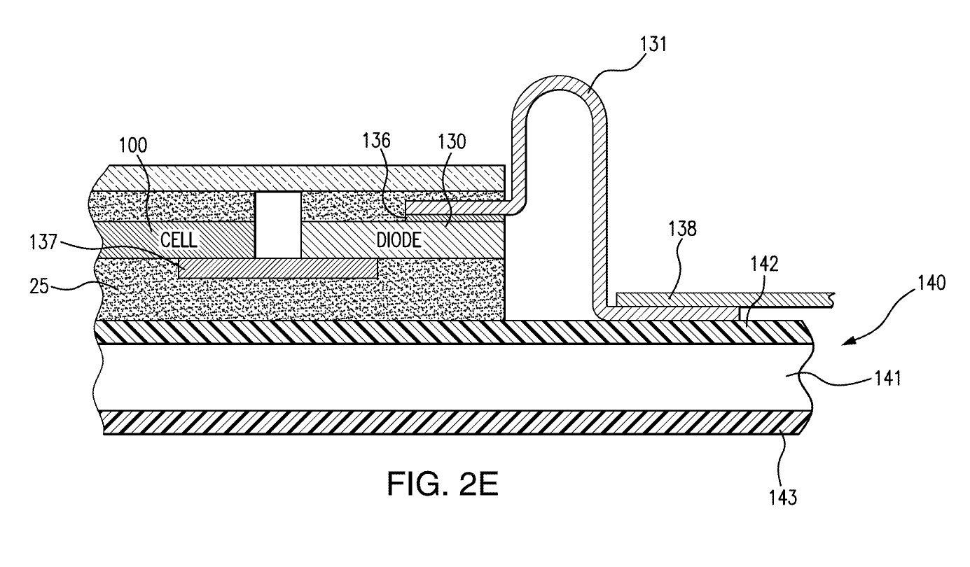

FIG. 2A schematically illustrates how a solar cell 100 with cropped corners can be provided with a bypass diode at one cropped corner, and FIG. 2B schematically illustrates how a bypass diode 110 is arranged in correspondence with one cropped corner and how two blocking diodes 130 and 140 are arranged in correspondence with two of the other cropped corners, in accordance with one embodiment of the disclosure. The two bypass diodes 130 and 140 have substantially triangular shapes, making efficient use of the space at the cropped corners.

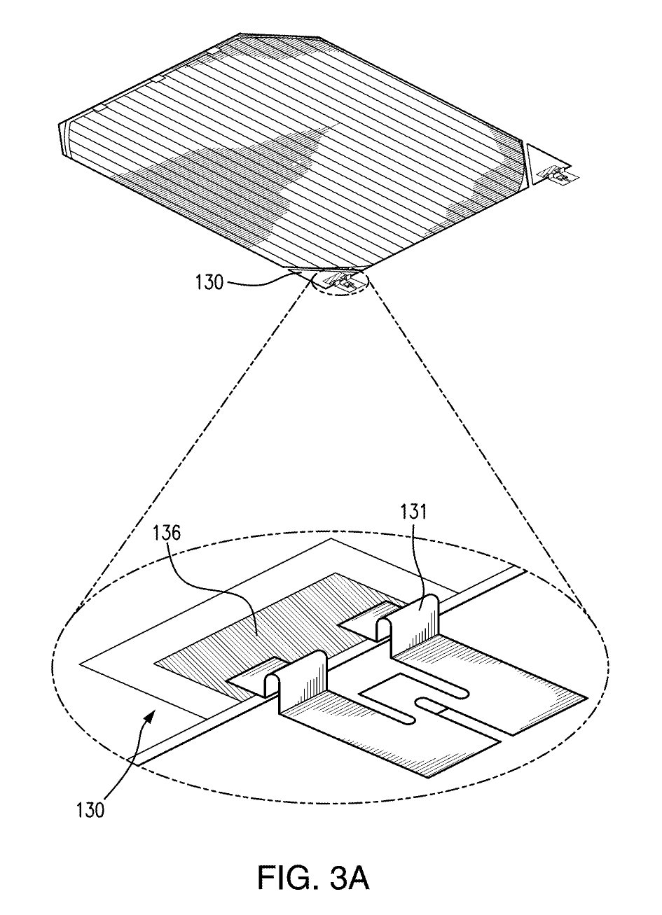

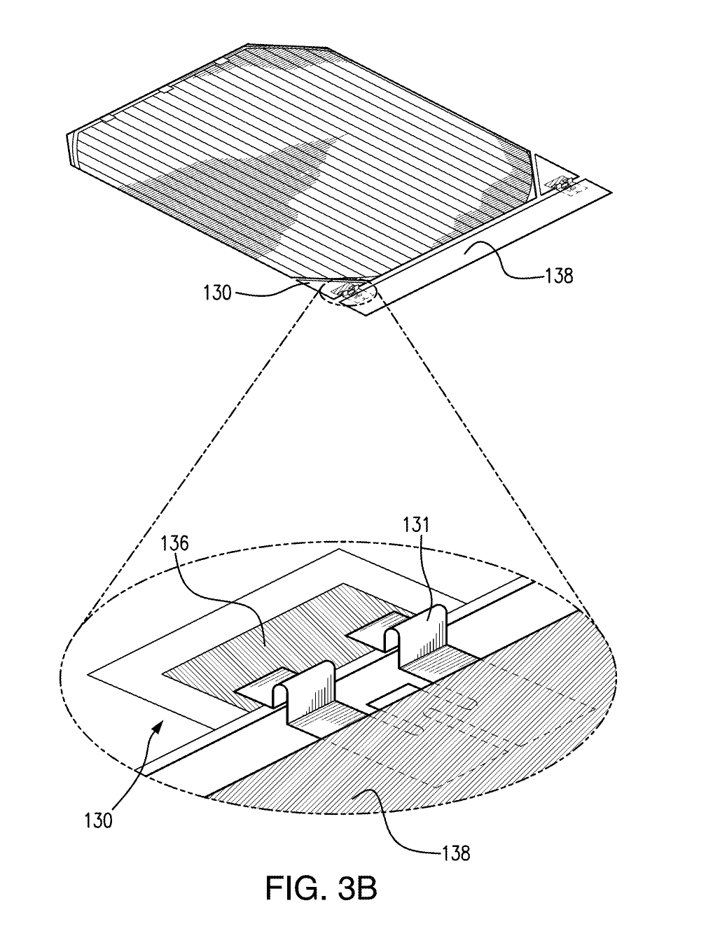

FIGS. 2C, 2D and 2E illustrate how, in accordance with one embodiment of the disclosure, the solar cell can be positioned on a laminar support 140 comprising three layers 141, 142 and 143, to which the solar cell 100 is joined by an adhesive layer 25. The blocking diode 130 is connected to the solar cell 100 by means of a connector 137 which in some embodiments is dispersed in a cut-out region of the adhesive layer 25. The blocking diode 130 includes a terminal 136 by means of which it can be connected to a metallic connecting member or interconnect 131, by means of which the terminal 136 of the blocking diode can be connected to a metal bus bar 138. FIGS. 3A and 3B schematically illustrate how one end of the interconnect 131 can be attached to the terminal 136 of the blocking diode at an upper portion of the blocking diode, and how an opposite end of the interconnect 131 can be sandwiched between the bus bar 138 and the laminar support 140.

The interconnect illustrated in FIGS. 3A and 3B is sometimes referred to as a “Z Interconnect”. The interconnect 131 can include, for example, first and second flat contact members that extend outward for contact, respectively, with two different portions of the terminal 136. An advantage of providing two separate contact members to two different portions of the terminal 136 is that thereby one can achieve improved reliability in the event one of the electrical contacts is broken. The interconnect 131 is serpentine shaped, with middle portions for electrical contact with the bus bar 138. The interconnect 131 can include one or more gaps where the planar surface changes direction, for stress relief.

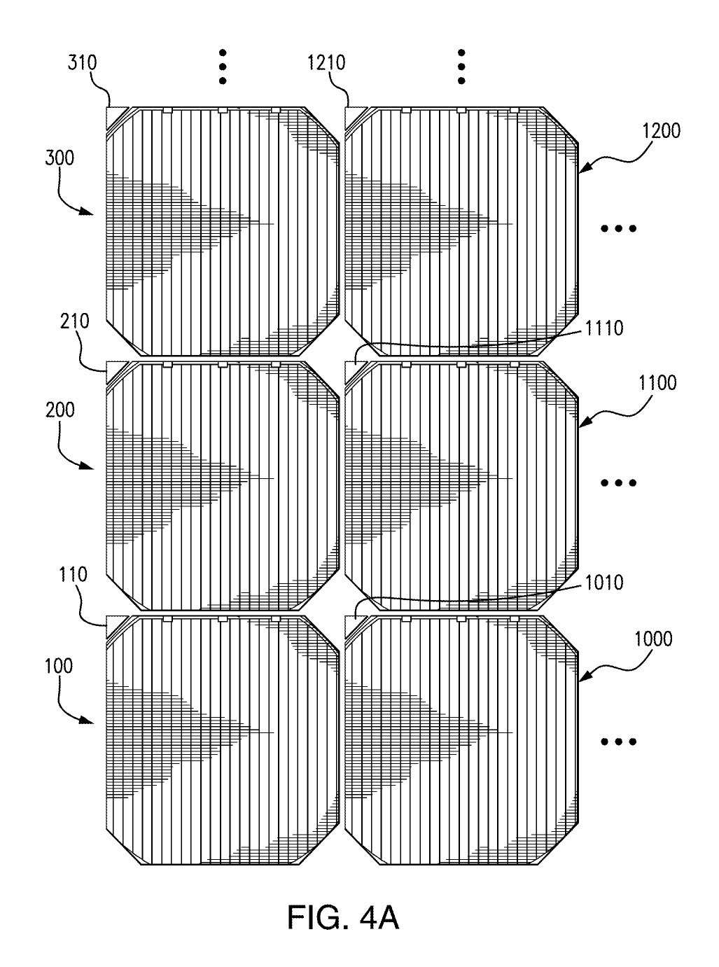

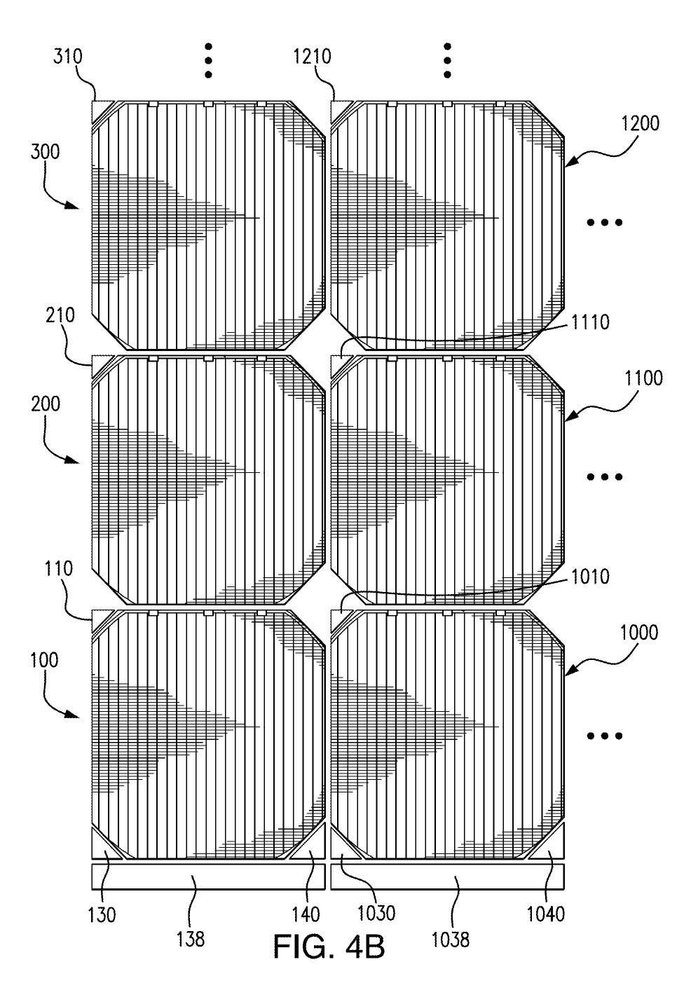

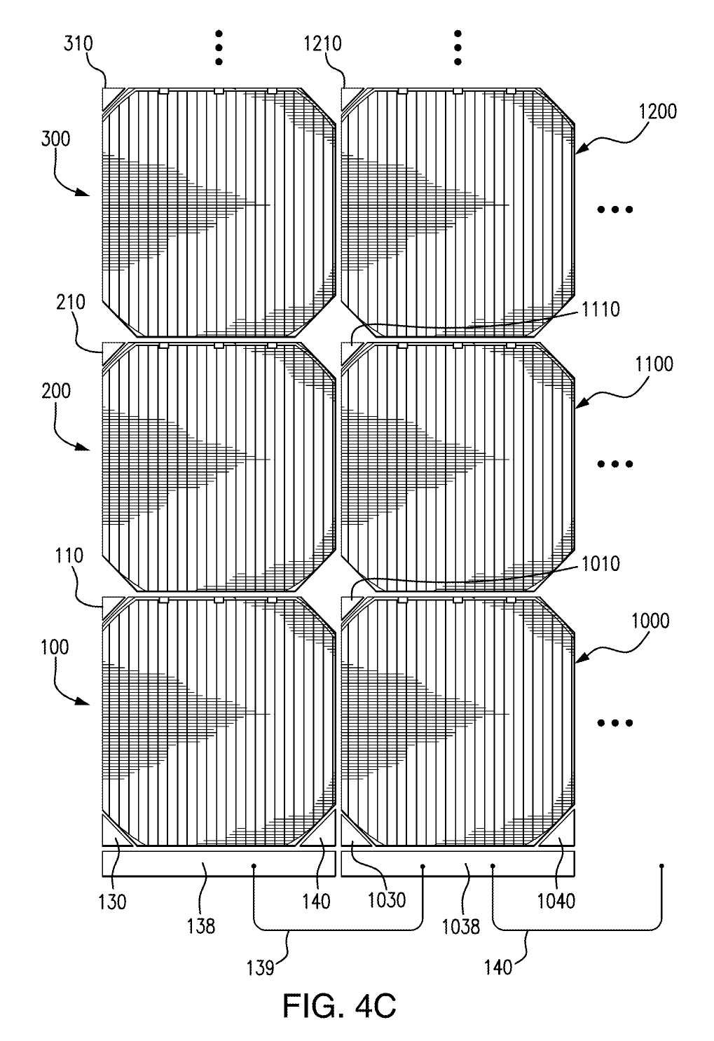

FIG. 4A illustrates an array of solar cells comprising a first string of series connected solar cells 100, 200 and 300 each provided with a bypass diode 110, 210, 310, and a second string of solar cells 1000, 1100, 1200, each provided with a bypass diode 1010, 1110, 1210. The bypass diode is placed in correspondence with a cropped corner of the respective solar cell, thus making use of the space that is left free between adjacent solar cells due to the cropped corners, as shown in FIG. 4A. Solar cells 100, 200 and 300 are connected in series, and so are solar cells 1000, 1100 and 1200. Each string can comprise a large number of solar cells, and the solar cell assembly or array can comprise a large number of strings.

FIG. 4B illustrates how the string of series connected solar cells 100, 200 and 300 is connected to the metal bus bar 138 through two blocking diodes 130 and 140, and how the string of series connected solar cells 1000, 1100 and 1200 is connected to the metal bus bar 1038 through two blocking diodes 1030 and 1040. In FIG. 4C, it is further shown how the two strings are connected in series by a connector 139 interconnecting the two bus bars 138 and 1038, and to a further string (not shown) by connector 140.

In FIG. 4C it can be seen how the blocking diodes 130, 140, 103 and 1040 have a polygonal shape, in this particular embodiment of the disclosure, a triangular shape. Thereby, efficient use is made of the space available at the ends of each string, between the final solar cell 100 and 1000 of the respective string, and the bus bars 138 and 1038, at which the current produced by the entire string is collected. The substantially triangular shape can be especially preferred in view of the fact that sometimes, due to the total amount of current produced by a string and also to enhance reliability, it can be appropriate to have two blocking diodes per string. In such a case, as shown in FIG. 4C, blocking diodes 140 and 1030 can be placed next to each other, efficiently making use of the triangular space available between the adjacent cropped corners of the two solar cells 100 and 1000 and the contact members 138 and 1038.

In this text, the term “comprises” and its derivations (such as “comprising”, etc.) should not be understood in an excluding sense, that is, these terms should not be interpreted as excluding the possibility that what is described and defined may include further elements, steps, etc.

The disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A solar cell assembly comprising:
a first string of series connected first solar cells, one of said first solar cells being a final first solar cell of the first string, said final first solar cell having at least one oblique cut corner; and
at least one contact member connected to said final first solar cell through a first blocking diode with the first blocking diode being positioned in correspondence with the space provided by said oblique cut corner.

2. The solar cell assembly of claim 1, wherein said first blocking diode has a substantially triangular shape adapted to fit into a space left free by said cut corner.

3. The solar cell assembly of claim 1, wherein said contact member is a metal bus bar.

4. The solar cell assembly of claim 1, further comprising a second string of series connected second solar cells, one of said second solar cells being a final second solar cell of the second string, said final second solar cell being connected to a contact member through a second blocking diode, the final first solar cell and the final second solar cell being placed adjacent to each other, said first blocking diode being placed in correspondence with an oblique cut corner of said final first solar cell and said second blocking diode being placed in correspondence with an oblique cut corner of said final second solar cell, said first blocking diode and said second blocking diode being placed adjacent to each other.

5. The solar cell assembly of claim 4, wherein said first blocking diode and said second blocking diode each have a substantially triangular or rectangular shape.

6. The solar cell assembly of claim 1, wherein said final first solar cell is connected to the contact member through two blocking diodes, one of said two blocking diodes being placed in correspondence with a first oblique cut corner of the final first solar cell, and the other one of said two blocking diodes being placed in correspondence with a second oblique cut corner of the final first solar cell.

7. The solar cell assembly of claim 6, wherein each of said two blocking diodes has a substantially triangular shape.

8. The solar cell assembly of claim 1, wherein said contact member is a metal bus bar having a substantially rectangular shape.

9. A solar cell assembly comprising a plurality of solar cells arranged adjacent to each other in rows and columns forming an array, each solar cell having a substantially rectangular shape with four oblique cut corners, each of a plurality of said solar cells being connected to a bypass diode arranged in correspondence with an oblique cut corner of the respective solar cell and arranged in a space provided between adjacent solar cells at the oblique cut corners of the solar cells, said solar cell assembly further comprising at least one contact member arranged to collect current from a plurality of said solar cells arranged in series, at least one solar cell being connected to said contact member through at least one blocking diode, the at least one blocking diode being placed in a space provided between said at least one solar cell and the contact member, in correspondence with one of the oblique cut corners of said at least one solar cell.

10. The solar cell assembly of claim 9, wherein said blocking diode has a substantially triangular shape.

11. The solar cell assembly of claim 9, said at least one solar cell being connected to said contact member through two blocking diodes, one of said blocking diodes being placed in a space provided between said at least one solar cell and the contact member in correspondence with one of the oblique cut corners of said at least one solar cell, and the other one of said blocking diodes being placed in a space provided between said at least one solar cell and the contact member in correspondence with another one of the oblique cut corners of said at least one solar cell.

12. The solar cell assembly of claim 9, wherein said contact member is a metal bus bar having a substantially rectangular shape.

13. The solar cell assembly of claim 9, wherein two blocking diodes are placed in a space between two adjacent solar cells belonging to two strings of series connected solar cells, and two metallic contact members connected in series, a first one of said blocking diodes interconnecting a first one of said two adjacent solar cells and one of said two metallic contact members, and a second one of said blocking diodes interconnecting a second one of said two adjacent solar cells and another one of said two metallic contact members, the first blocking diode being placed in correspondence with an oblique cut corner of the first one of said two adjacent solar cells, and the second blocking diode being placed in correspondence with an oblique cut corner of the second one of said two adjacent solar cells.

14. The solar cell assembly of claim 13, each of said two blocking diodes having a substantially triangular shape.
